(19) United States
(12) Patent Application Publication
(10) Pub. No.: US 2024/0048170 A1
(43) Pub. Date: Feb. 8, 2024

(54) ELECTRONIC DEVICE FOR PROCESSING WIRELESS SIGNAL, AND OPERATION METHOD THEREOF

(71) Applicant: SAMSUNG ELECTRONICS CO., LTD., Suwon-si (KR)

(72) Inventors: Taeyoung KIM, Suwon-si (KR); Jonghyun PARK, Suwon-si (KR); Dongil YANG, Suwon-si (KR); Hyoseok NA, Suwon-si (KR)

(73) Assignee: SAMSUNG ELECTRONICS CO., LTD., Suwon-si (KR)

(21) Appl. No.: 18/379,927

(22) Filed: Oct. 13, 2023

Related U.S. Application Data
(63) Continuation of application No. PCT/KR2022/005260, filed on Apr. 12, 2022.

(30) Foreign Application Priority Data
Apr. 13, 2021 (KR) 10-2021-0047547

(51) Int. Cl. H04B 1/40

(52) U.S. Cl. CPC H04B 1/40

(57) ABSTRACT

An electronic device includes: an antenna; a radio frequency front end (RFFE) operatively connected to the antenna; and a radio frequency integrated circuit (RFIC) operatively connected to the RFFE, wherein the RFFE includes: a high pass filter provided on a first electrical path between the antenna and the RFIC; a first band pass filter provided on the first electrical path between the high pass filter and the RFIC, the first band pass filter being configured to filter a signal of a first frequency band; and a second band pass filter provided on a second electrical path branched from the first electrical path between the antenna and the high pass filter, the second band pass filter being configured to filter a signal of a second frequency band relatively lower than the first frequency band.

### CROSS-REFERENCE TO RELATED APPLICATIONS

This application is a by-pass continuation application of International Application No. PCT/KR2022/005260, filed on Apr. 12, 2022, which is based on and claims priority to Korean Patent Application No. 10-2021-0047547, filed on Apr. 13, 2021, in the Korean Intellectual Property Office, the disclosures of which are incorporated by reference herein their entireties.

### BACKGROUND

### 1. Field

The disclosure relates to a device and method for processing a wireless signal in an electronic device.

### 2. Description of Related Art

The development of information and communication technology and semiconductor technology may allow electronic devices to have various functions. For example, electronic devices may provide a short-range wireless communication function (e.g., Bluetooth, wireless local area network (LAN), or near field communication (NFC)) and/or a mobile communication function (e.g., long-term evolution (LTE), LTE-advanced (LTE-A) or 5th generation new radio (5G NR)).

An electronic device may generate a radio frequency (RF) signal for wireless communication. A circuit (e.g., a radio frequency front end (RFFE)) for processing the RF signal may be included in the electronic device.

A circuit (e.g., an RFFE) for processing an RF signal may require a relatively large physical area as the structure thereof becomes relatively complex. For example, the circuit for processing an RF signal may include at least one band pass filter (BPF) and a diplexer. The band pass filter and/or the diplexer may be disposed on one surface of a substrate included in the electronic device based on a surface mounter technology.

The band pass filter and/or the diplexer may be disposed on one surface of a substrate included in the electronic device and thus occupy a portion of an internal space of the electronic device. Accordingly, it may be difficult to secure space for arranging components inside the electronic device. The band pass filter and/or the diplexer disposed on one surface of a substrate included in the electronic device may be damaged or separated when assembled or external impact is applied.

### SUMMARY

Provided are a device and method for reducing complexity of a circuit for processing an RF signal in an electronic device.

According to an aspect of the disclosure, an electronic device includes: an antenna; a radio frequency front end (RFFE) operatively connected to the antenna; and a radio frequency integrated circuit (RFIC) operatively connected to the RFFE, wherein the RFFE includes: a high pass filter provided on a first electrical path between the antenna and the RFIC; a first band pass filter provided on the first electrical path between the high pass filter and the RFIC, the first band pass filter being configured to filter a signal of a first frequency band; and a second band pass filter provided on a second electrical path branched from the first electrical path between the antenna and the high pass filter, the second band pass filter being configured to filter a signal of a second frequency band relatively lower than the first frequency band.

The electronic device may further include: a housing; and a substrate provided inside the housing, wherein the high pass filter is provided on the substrate.

The substrate may include a plurality of layers that are stacked, wherein the high pass filter may be provided on the plurality of layers.

The high pass filter comprises a first capacitor, a second capacitor, a third capacitor, a fourth capacitor, a first inductor, and a second inductor, wherein a first terminal of the first capacitor is connected to a first port of the high pass filter connected to the antenna, and a second terminal of the first capacitor is connected to a first terminal of the second capacitor, wherein a second terminal of the second capacitor is connected to a first terminal of the fourth capacitor, wherein a second terminal of the fourth capacitor is connected to a second port of the high pass filter connected to the first band pass filter, wherein a first terminal of the third capacitor is connected to a first branched point of an electrical path between the one terminal of the first capacitor and the antenna, and a second terminal of the third capacitor is connected to a second branched point of an electrical path between the second terminal of the second capacitor and the first terminal of the fourth capacitor, wherein a first terminal of the first inductor is connected to a third branched point of an electrical path between the second terminal of the first capacitor and the first terminal of the second capacitor, and a second terminal of the first inductor is connected to a ground provided on the substrate, and wherein a first terminal of the second inductor is connected to a fourth branched point of an electrical path between the first terminal of the fourth capacitor and the second branched point, and a second terminal of the second inductor is connected to a fifth branched point of an electrical path between the second terminal of the fourth capacitor and the second port of the high pass filter.

The plurality of layers of the substrate may include a first layer, a second on a bottom of the first layer, a third layer stacked on a bottom of the second layer, and a fourth layer on a bottom of the third layer, wherein the first capacitor comprises a first conductive part of the first layer of the substrate and a second conductive part of the second layer, wherein the second capacitor comprises a third conductive part of the first layer and a fourth conductive part of the second layer, wherein the third capacitor comprises the second conductive part of the second layer and a fifth conductive part of the third layer, wherein the fourth capacitor comprises a sixth conductive part of the third layer and a seventh conductive part of the fourth layer, wherein the first inductor comprises a first conductive pattern having a first length on the fourth layer, and wherein the second inductor.

The ground may include a ground pattern provided on each layer of the plurality of layers of the substrate.

The first port and the second port of the high pass filter may be provided on a surface of the substrate.

The first band pass filter or the second band pass filter may be provided on at least a partial area at least partially overlapping the high pass filter on a surface of the substrate.

The second band pass filter may be provided in a first area at least partially overlapping the high pass filter on a surface of the substrate, and wherein the first band pass filter is provided in a second area on a surface of the substrate, which is different from the first area, the first band pass filter being not overlapping the high pass filter provided on the substrate.

The first frequency band may include a frequency band of 3 GHz or higher, wherein the second frequency band may include a frequency band of 3 GHz or lower.

The electronic device may further include a matching circuit provided on the second electrical path between the antenna and the second band pass filter.

The second electrical path may be open in the first frequency band.

The first electrical path may be open in the second frequency band.

The RFFE may further include: a first amplification circuit configured to amplify a first radio frequency (RF) signal provided from the RFIC and output the first RF signal to the first band pass filter; a first low noise amplification circuit configured to amplify low noise of a second RF signal provided from the first band pass filter and output the second RF signal to the RFIC; a second amplification circuit configured to amplify a third RF signal provided from the RFIC and output the third RF signal to the second band pass filter; and a second low noise amplification circuit configured to amplify low noise of a fourth RF signal provided from the second band pass filter and output the fourth RF signal to the RFIC.

The electronic device may further include a processor operatively connected to the RFIC, wherein the processor is configured to process a baseband signal provided from the RFIC.

According to one or more embodiments of the disclosure, an electronic device may separate RF signals of different frequency bands by using a high pass filter (HPF) or a low pass filter (LPF) included on a substrate (or in a substrate) to reduce complexity of a circuit (e.g., a RFFE) for processing an RF signal and secure a space for arranging components inside the electronic device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to an embodiment;

FIG. 2 is an example of a block diagram illustrating an electronic device including a high pass filter according to one or more embodiments; embodiments;

FIG. 3A is a circuit diagram of a high pass filter according to one or more

FIG. 3B is a diagram illustrating a stacking structure of a high pass filter according to one or more embodiments;

FIG. 3C is a diagram illustrating a stacking structure of a high pass filter according to one or more embodiments;

FIG. 3D is a diagram illustrating a stacking structure of a high pass filter according to one or more embodiments;

FIG. 3E is a diagram illustrating a stacking structure of a high pass filter according to one or more embodiments;

FIG. 4 is a graph depicting filtering performance of a high pass filter according to one or more embodiments;

FIG. 5 is an example of a block diagram illustrating an electronic device including a low pass filter according to one or more embodiments; embodiments;

FIG. 6A is a circuit diagram of a low pass filter according to one or more

FIG. 6B is a diagram illustrating a stacking structure of a low pass filter according to one or more embodiments;

FIG. 6C is a diagram illustrating a stacking structure of a low pass filter according to one or more embodiments;

FIG. 6D is a diagram illustrating a stacking structure of a low pass filter according to one or more embodiments;

FIG. 7 is a graph depicting filtering performance of a low pass filter according to one or more embodiments;

FIG. 8 is another example of an electronic device including a low pass filter according to one or more embodiments; and

FIG. 9 is another example of an electronic device including a high pass filter according to one or more embodiments.

### DETAILED DESCRIPTION

Hereinafter, various embodiments will be described with reference to the accompanying drawings.

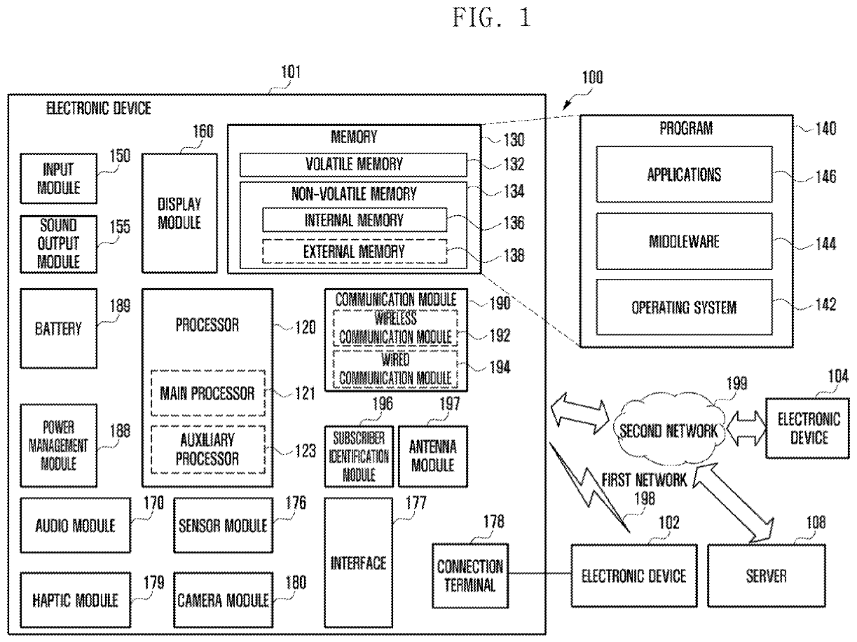

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC. According to an embodiment, the subscriber identification module 196 may include a plurality of subscriber identification modules. For example, the plurality of subscriber identification modules may store different subscriber information.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band. For example, the plurality of antennas may include a patch array antenna and/or a dipole array antenna.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

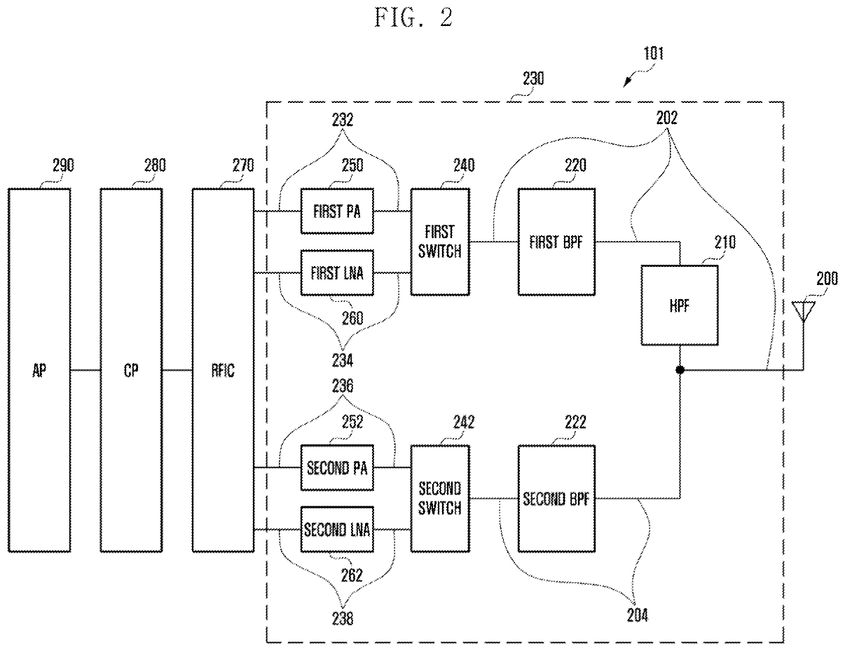

FIG. 2 is an example of a block diagram illustrating an electronic device including a high pass filter according to one or more embodiments.

According to various embodiment referring to FIG. 2, the electronic device 101 may include an antenna 200 (e.g., the antenna module 197 in FIG. 1), a radio frequency front end (RFFE) 230, a radio frequency integrated circuit (RFIC) 270, a communication processor (CP) 280 (e.g., the processor 120 or the auxiliary processor 123 in FIG. 1), and/or an application processor (AP) 290 (e.g., the processor 120 or the main processor 121 in FIG. 1). According to an embodiment, the RFFE 230 and/or the RFIC 270 may be substantially the same as the wireless communication circuit 192 in FIG. 1 or included in the wireless communication circuit 192.

According to one or more embodiments, the RFFE 230 may include a high pass filter (HPF) 210, a first band pass filter (BPF) 220, a second band pass filter 222, a first switch 240, a second switch 242, a first power amplifier (PA) 250, a second power amplifier (PA) 252, a first low noise amplifier (LNA) 260, and/or a second low noise amplifier (LNA) 262.

According to one or more embodiments, the high pass filter 210 may be disposed or provided on a first electrical path 202 between the antenna 200 and the first switch 240 and may filter a radio frequency (RF) signal of a first frequency band (e.g., about 3 GHz or higher). According to an embodiment, the high pass filter 210 may filter a signal of the first frequency band from the RF signal received through the antenna 200 and output the signal to the first band pass filter 220. According to an embodiment, the high pass filter 210 may filter a signal of the first frequency band from the RF signal provided from the first band pass filter 220 and output the signal to the antenna 200. According to an embodiment, the high pass filter 210 may be designed so that the first electrical path 202 is open in a second frequency band (e.g., about 3 GHz or lower). According to an embodiment, the high pass filter 210 may be configured such that the impedance is matched in the first band pass filter 220.

According to one or more embodiments, the first band pass filter 220 may be disposed or provided on the first electrical path 202 between the high pass filter 210 and the first switch 240 and may filter an RF signal in a third frequency band designated for transmission and/or reception of data in a network (e.g., the first network 198 or the second network 199 in FIG. 1). According to an embodiment, the first band pass filter 220 may filter a signal of the third frequency band from the signal of the first frequency band provided from the high pass filter 210 and output the signal to the first switch 240 (or the RFIC 270). According to an embodiment, the first band pass filter 220 may filter a signal of the third frequency band from the RF signal provided from the first switch 240 (or the RFIC 270) and output the signal to the high pass filter 210.

According to one or more embodiments, the second band pass filter 222 may be disposed or provided on a second electrical path 204 branched from the first electrical path 202 between the antenna 200 and the high pass filter 210 and may filter an RF signal in a fourth frequency band designated for transmission and/or reception of data in a network (e.g., the first network 198 or the second network 199 in FIG. 1). According to an embodiment, the second band pass filter 222 may filter a signal of the fourth frequency band from the RF signal received through the antenna 200 and the second electrical path 204 and output the signal to the second switch 242 (or the RFIC 270). According to an embodiment, the second band pass filter 222 may filter a signal of the fourth frequency band from the RF signal provided from the second switch 242 (or the RFIC 270) and output the signal to the antenna 200. According to an embodiment, the electronic device 101 may further include a matching circuit disposed or provided between the antenna 200 and the second band pass filter 222 on the second electrical path 204. For example, the matching circuit may be configured such that the impedance is matched in the second band pass filter 222. For example, the matching circuit may be designed so that the second electrical path 204 is open in the first frequency band (e.g., about 3 GHz or higher).

According to one or more embodiments, the first switch 240 may electrically or operatively connect the first electrical path 202 to the third electrical path 232 (e.g., the first power amplifier 250) or the fourth electrical path 234 (e.g., the first low noise amplifier 260). According to an embodiment, when transmitting a signal by using the third frequency band, the first switch 240 may electrically or operatively connect the first electrical path 202 and the third electrical path 232 (e.g., the first power amplifier 250), based on control of the communication processor 280. According to an embodiment, when receiving a signal by using the third frequency band, the first switch 240 may electrically or operatively connect the first electrical path 202 and the fourth electrical path 234 (e.g., the first low noise amplifier 260), based on control of the communication processor 280. According to an embodiment, the first power amplifier 250 may amplify the RF signal provided from the RFIC 270 and output the RF signal to the first band pass filter 220 through the first switch 240. According to an embodiment, the first low noise amplifier 260 may amplify low noise of the RF signal of the third frequency band provided from the first band pass filter 220 through the first switch 240 and output the RF signal to the RFIC 270.

According to one or more embodiments, the second switch 242 may electrically or operatively connect the second electrical path 204 to a fifth electrical path 236 (e.g., the second power amplifier 252) or a sixth electrical path 238 (e.g., the second low noise amplifier 262). According to an embodiment, when transmitting a signal by using the fourth frequency band, the second switch 242 may electrically or operatively connect the second electrical path 204 and the fifth electrical path 236 (e.g., the second power amplifier 252), based on control of the communication processor 280. According to an embodiment, when receiving a signal by using the fourth frequency band, the second switch 242 may electrically or operatively connect the second electrical path 204 and the sixth electrical path 238 (e.g., the second low noise amplifier 262), based on control of the communication processor 280. According to an embodiment, the second power amplifier 252 may amplify the RF signal provided from the RFIC 270 and output the RF signal to the second band pass filter 222 through the second switch 242. According to an embodiment, the second low noise amplifier 262 may amplify low noise of the RF signal of the fourth frequency band provided from the second band pass filter 222 through the second switch 242 and output the RF signal to the RFIC 270.

According to one or more embodiments, the RFIC 270 may process an RF signal for transmission and/or reception through the antenna 200. According to an embodiment, the RFIC 270 may up-convert a baseband signal (or intermediate frequency signal) provided from the communication processor 280 into an RF signal in a predetermined band. According to an embodiment, the RFIC 270 may down-convert an RF signal provided from the first low noise amplifier 260 or the second low noise amplifier 262 into a baseband signal (or intermediate frequency signal).

According to one or more embodiments, the communication processor 280 may generate a baseband signal for wireless communication. According to an embodiment, the communication processor 280 may provide a baseband signal to the RFIC 270. According to an embodiment, the communication processor 280 may process a baseband signal (or intermediate frequency signal) provided from the RFIC 270.

According to one or more embodiments, the application processor 290 may perform various data processing or operations to control at least one other component (e.g., the communication processor 280) included in the electronic device 101.

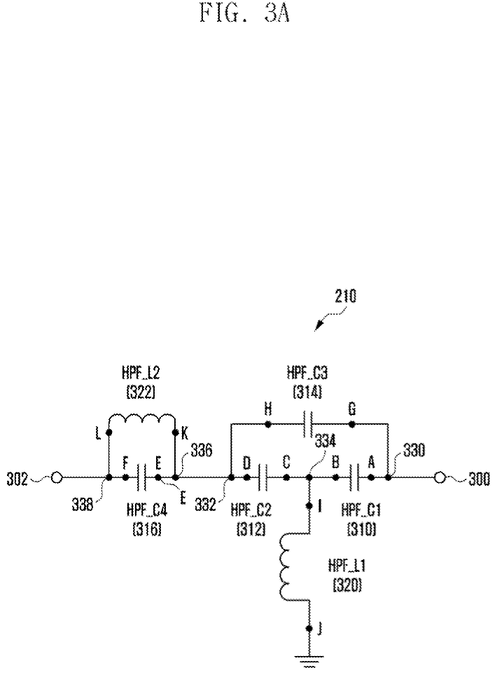

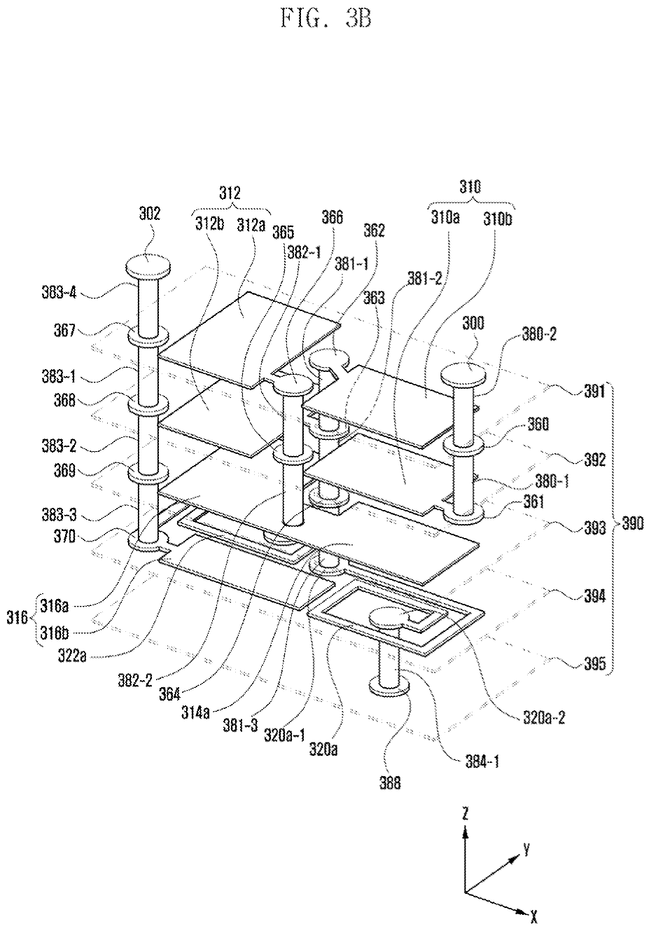

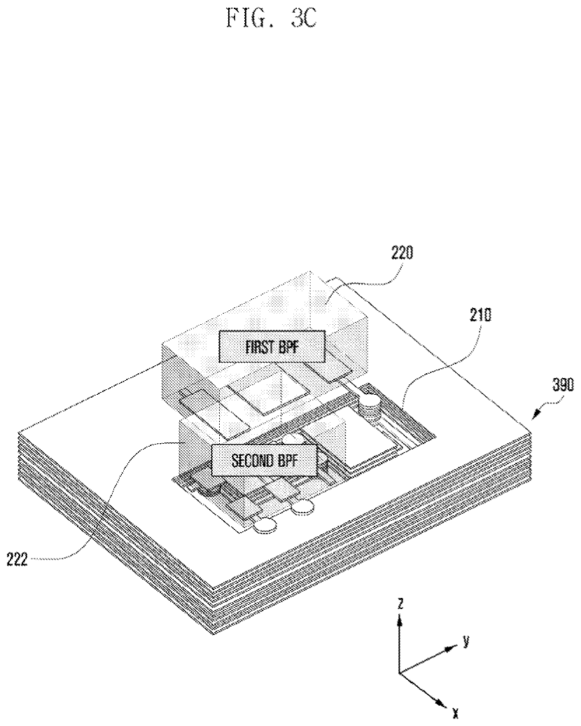

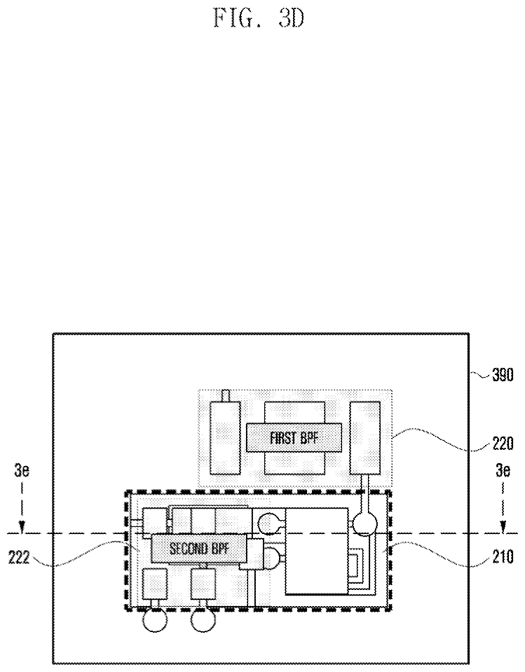

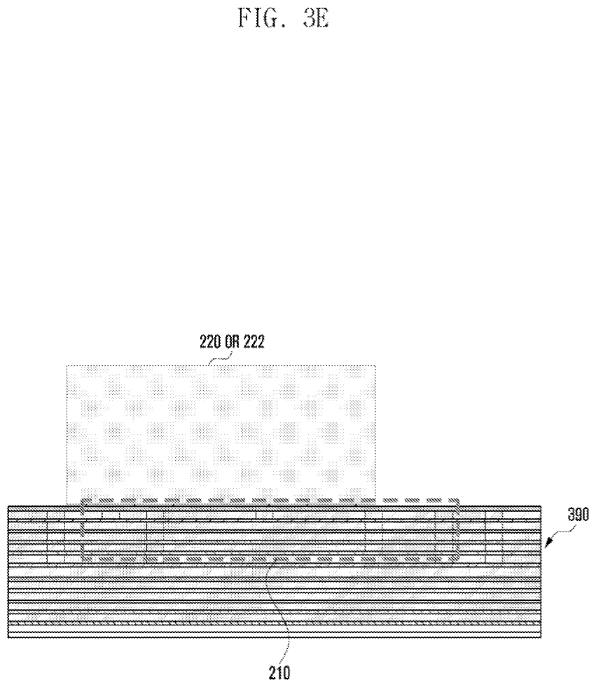

FIG. 3A is a circuit diagram of a high pass filter according to one or more embodiments.

According to one or more embodiments referring to FIG. 3A, the high pass filter 210 may include a first capacitor (HPF_C1) 310, a second capacitor (HPF_C2) 312, a third capacitor (HPF_C3) 314, a fourth capacitor (HPF_C4) 316, a first inductor (HPF_L1) 320 and/or a second inductor (HPF_L2) 322.

According to one or more embodiments, one terminal A of the first capacitor 310 may be connected to a first port 300 of the high pass filter 210 and the other terminal B of the first capacitor 310 may be connected to one terminal C of the second capacitor 312. The other terminal D of the second capacitor 312 may be connected to one terminal E of the fourth capacitor 316. The other terminal F of the fourth capacitor 316 may be connected to a second port 302 of the high pass filter 210. For example, the first port 300 of the high pass filter 210 may be connected to the antenna 200 through the first electrical path 202. For example, the second port 302 of the high pass filter 210 may be connected to the first band pass filter 220 through the first electrical path 202.

According to one or more embodiments, one terminal G of the third capacitor 314 may be connected to a first branched point 330 of an electrical path between the one terminal A of the first capacitor 310 and the first port 300. The other terminal H of the third capacitor 314 may be connected to a second branched point 332 of an electrical path between the other terminal D of the second capacitor 312 and the one terminal E of the fourth capacitor 316.

According to one or more embodiments, one terminal I of the first inductor 320 may be connected to a third branched point 334 of an electrical path between the other terminal B of the first capacitor 310 and the one terminal C of the second capacitor 312. The other terminal J of the first inductor 320 may be connected to a ground disposed or provided on a substrate 390.

According to one or more embodiments, one terminal K of the second inductor 322 may be connected to a fourth branched point 336 of an electrical path between the one terminal E of the fourth capacitor 316 and the second branched point 332. The other terminal K of the second inductor 322 may be connected to a fifth branched point 338 of an electrical path between the other terminal F of the fourth capacitor 316 and the second port 302.

According to one or more embodiments, in the circuit configuration of FIG. 3A, a combination of the first capacitor 310, the second capacitor 312, and the first inductor 320 may operate as a filter for passing an RF signal of the first frequency band. A combination of the fourth capacitor 316 and the second inductor 322, and the third capacitor 314 may operate as a filter for blocking passage of an RF signal of the second frequency band.

FIG. 3B, FIG. 3C, FIG. 3D, and FIG. 3E are diagrams illustrating a stacking structure of a high pass filter according to one or more embodiments. FIG. 3E is a partial sectional view of the electronic device viewed along line 3e-3e of FIG. 3D according to one or more embodiments of the disclosure.

According to one or more embodiments referring to FIG. 3B, FIG. 3C, FIG. 3D, and FIG. 3E, the high pass filter 210 may be disposed or provided on the substrate 390. According to an embodiment, as shown in FIG. 3A, the first capacitor (HPF_C1) 310, the second capacitor (HPF_C2) 312, the third capacitor (HPF_C3) 314, the fourth capacitor (HPF_C4) 316, the first inductor (HPF_L1) 320, and/or the second inductor (HPF_L2) 322 included in the high pass filter 210 may be configured as a stacking structure on the substrate 390. According to an embodiment, the substrate 390 may include a first layer 391, a second layer 392, a third layer 393, a fourth layer 394, and a fifth layer 395. According to an embodiment, the first layer 391, the second layer 392, the third layer 393, the fourth layer 394, and/or the fifth layer 395 may be sequentially stacked. For example, the substrate 390 may be disposed or provided in an internal space of a housing of the electronic device 101.

According to one or more embodiments, on the first layer 391, a first conductive part 310a of the first capacitor 310 and a first conductive part 312a of the second capacitor 312 may be configured. On the second layer 392, a second conductive part 310b of the first capacitor 310 and a second conductive part 312b of the second capacitor 312 may be configured. According to an embodiment, on the first layer 391, a first contact point 360 separated from the first conductive part 310a of the first capacitor 310 may be configured. A second contact point 361 extending from the second conductive part 310b of the first capacitor 310 may be connected to the first contact point 360 though a first via 380-1. For example, the first contact point 360 may be connected to the first port 300 through a second via 380-2. According to an embodiment, a third contact point 362 extending from the first conductive part 310a of the first capacitor 310 on the first layer 391 may be connected through a third via 381-1 to a fourth contact point 363 extending from the second conductive part 312b of the second capacitor 312 on the second layer 392.

According to an embodiment, the first capacitor 310 may be configured by the first conductive part 310a of the first capacitor 310 disposed or provided on the first layer 391 and the second conductive part 310b of the first capacitor 310 disposed or provided on the second layer 392, which is configured to at least partially overlap the first conductive part 310a of the first capacitor 310 when viewed in the z-axis direction. According to an embodiment, the second capacitor 312 may be configured by the first conductive part 312a of the second capacitor 312 disposed or provided on the first layer 391 and the second conductive part 312b of the second capacitor 312 disposed or provided on the second layer 392, which is configured to at least partially overlap the first conductive part 312a of the second capacitor 312 when viewed in the z-axis direction.

According to one or more embodiments, on the third layer 393, a first conductive part 314a of the third capacitor 314 and/or a first conductive part 316a of the fourth capacitor 316 may be configured. On the fourth layer 394, a conductive pattern 320a of the first inductor 320, a second conductive part 316b of the fourth capacitor 316, and a conductive pattern 322a of the second inductor 322 may be configured.

According to an embodiment, on the third layer 393, a fifth contact point 364 separated from the first conductive part 314a of the third capacitor 314 may be configured. On the second layer 392, a fourth contact point 363 extending from the second conductive part 312b of the second capacitor 312 may be connected to the fifth contact point 364 though a fourth 381-2. The fifth contact point 364 may be connected to one terminal 320a-1 of the conductive pattern 320a of the first inductor 320 through a fifth via 381-3 on the fourth layer 394. The other terminal 320a-2 of the conductive pattern 320a of the first inductor 320 may be connected to the ground 388 of the fifth layer 395 through a sixth via 384-1. For example, the ground 388 may include a pattern disposed or provided on the fifth layer 395 of the substrate 390.

According to an embodiment, on the second layer 392, the sixth contact point 365 separated from the second conductive part 312b of the second capacitor 312 may be configured. On the first layer 391, a seventh contact point 366 extending from the first conductive part 312a of the second capacitor 312 may be connected to the sixth contact point 365 though a seventh via 382-1. The sixth contact point 365 may be connected to the first conductive part 316a of the fourth capacitor 316 of the third layer 393 through an eighth via 382-2.

According to an embodiment, on the first layer 391, an eighth contact point 367 separated from the first conductive part 312a of the second capacitor 312 may be configured. On the second layer 392, the eighth contact point 367 may be connected to a ninth contact point 368 separated from the second conductive part 312b of the second capacitor 312 through a ninth via 383-1. On the third layer 393, the ninth contact point 368 may be connected to a tenth contact point 369 separated from the first conductive part 316a of the fourth capacitor 316 through a tenth via 383-2. On the fourth layer 394, the tenth contact point 369 may be connected to an eleventh contact point 370 extending from the second conductive part 316b of the fourth capacitor 316 through an eleventh via 383-3. For example, the eighth contact point 367 may be connected to the second port 302 through a twelfth via 383-4.

According to an embodiment, the third capacitor 314 may be configured by the second conductive part 310b of the first capacitor 310 disposed or provided on the second layer 392 and the first conductive part 314a of the third capacitor 314 disposed or provided on the third layer 393, which is configured to at least partially overlap the second conductive part 310b of the first capacitor 310 when viewed in the z-axis direction. According to an embodiment, the fourth capacitor 316 may be configured by the first conductive part 316a of the fourth capacitor 316 disposed or provided on the third layer 393 and the second conductive part 316b of the fourth capacitor 316 disposed or provided on the fourth layer 394, which is configured to at least partially overlap the first conductive part 316a of the fourth capacitor 316 when viewed in the z-axis direction. According to an embodiment, one terminal of the conductive pattern 322a of the second inductor 322 may be connected to the eleventh contact point 370 (e.g., the other terminal F of the fourth capacitor 316) extending from the second conductive part 316b of the fourth capacitor 316. In one embodiment, the other terminal of the conductive pattern 322a of the second inductor 322 may be connected to the ground of the fifth layer 395 through a thirteenth via.

According to one or more embodiments, the first band pass filter 220 and the second band pass filter 222 may be arranged or provided on a surface of the substrate 390. According to an embodiment, when viewed in the z-axis direction, the second band pass filter 222 may be disposed or provided on a surface of the substrate 390 to overlap the high pass filter 210 and/or at least a portion of the high pass filter 210 disposed or provided on the substrate 390. According to an embodiment, as shown in FIG. 3C and FIG. 3D, the first band pass filter 220 may be disposed or provided on a surface of the substrate 390 not to overlap the high pass filter 210 disposed or provided on the substrate 390.

According to one or more embodiments, the first port 300 and the second port 302 of the high pass filter 210 may be disposed or provided on a surface of the substrate 390.

According to one or more embodiments, when viewed in the z-axis direction, the first band pass filter 220 and the second band pass filter 222 may be arranged or provided on a surface of the substrate 390 to overlap the high pass filter 210 and/or at least a portion of the high pass filter 210 disposed or provided on the substrate 390. According to an embodiment, when viewed in the z-axis direction, the first band pass filter 220 and the second band pass filter 222 may be arranged or provided on a surface of the substrate 390 to be included in an area of the high pass filter 210 disposed or provided on the substrate 390. In this case, the electronic device 101 may minimize and/or optimize wires for electrical connection among the first band pass filter 220, the second band pass filter 222, and/or the high pass filter 210.

According to one or more embodiments, when viewed in the z-axis direction, the first band pass filter 220 may also be disposed or provided on a surface of the substrate 390 to overlap the high pass filter 210 and/or at least a portion of the high pass filter 210 disposed or provided on the substrate 390. The second band pass filter 222 may also be disposed or provided on a surface of the substrate 390 not to overlap the high pass filter 210 disposed or provided on the substrate 390.

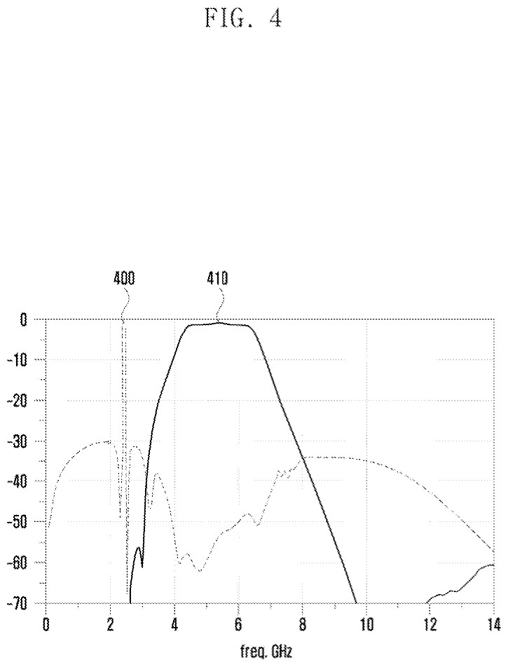

FIG. 4 is a graph depicting filtering performance of a high pass filter according to one or more embodiments. By way of example, the horizontal axis of FIG. 4 may represent frequency (GHz), and the vertical axis may represent signal level (dB).

According to various embodiment referring to FIG. 4, in case that the electronic device 101 uses the high pass filter 210, an RF signal of the first frequency band (e.g., about 3 GHz or higher) among RF signals received through the antenna 200 may be output to the first band pass filter 220 through the high pass filter 210. In case that the electronic device 101 uses the high pass filter 210, an RF signal of the second frequency band (e.g., about 3 GHz or lower) among RF signals received through the antenna 200 may be output to the second band pass filter 222 (400).

According to one or more embodiments, an electronic device (e.g., the electronic device 101 in FIG. 1 or FIG. 2) may include an antenna (e.g., the antenna module 197 in FIG. 1 or the antenna 200 in FIG. 2), an RFFE (e.g., the wireless communication module 192 in FIG. 1 or the RFFE 230 in FIG. 2) electrically or operatively connected to the antenna, and an RFIC (e.g., the wireless communication module 192 in FIG. 1 or the RFIC 270 in FIG. 2) electrically or operatively connected to the RFFE, wherein the RFFE includes a high pass filter (e.g., the high pass filter 210 in FIG. 2, FIG. 3A, FIG. 3B, FIG. 3C, FIG. 3D, or FIG. 3E) disposed or provided on a first electrical path (e.g., the first electrical path 202 in FIG. 2) between the antenna and the RFIC, a first band pass filter (e.g., the first band pass filter 220 in FIG. 2, FIG. 3C, FIG. 3D, or FIG. 3E) that is disposed or provided, between the high pass filter and the RFIC, on the first electrical path and filters a signal of a first frequency band, and a second band pass filter (e.g., the second band pass filter 222 in FIG. 2, FIG. 3C, FIG. 3D, or FIG. 3E) that is disposed or provided on a second electrical path (e.g., the second electrical path 204 in FIG. 2) branched from the first electrical path between the antenna and the high pass filter and filters a signal of a second frequency band relatively lower than the first frequency band.

According to one or more embodiments, the electronic device may further include a housing and a substrate (e.g., the substrate 390 in FIG. 3A, FIG. 3B, FIG. 3C, FIG. 3D, or FIG. 3E) disposed or provided inside the housing, and the high pass filter may be disposed or provided on the substrate.

According to one or more embodiments, the high pass filter may include a first capacitor (e.g., the first capacitor (HPF_C1) 310 in FIG. 3A), a second capacitor (e.g., the second capacitor (HPF_C2) 312 in FIG. 3A), a third capacitor (e.g., the third capacitor (HPF_C3) 314 in FIG. 3A), a fourth capacitor (e.g., the fourth capacitor (HPF_C4) 316 in FIG. 3A), a first inductor (e.g., the first inductor (HPF_L1) 320 in FIG. 3A) and/or a second inductor (e.g., the second inductor (HPF_L2) 322 in FIG. 3A), wherein one terminal (e.g., the one terminal A of the first capacitor 310 in FIG. 3A) of the first capacitor is connected to a first port (e.g., the first port 300 in FIG. 3A) of the high pass filter connected to the antenna, the other terminal (e.g., the other terminal B of the first capacitor 310 in FIG. 3A) of the first capacitor is connected to one terminal (e.g., the one terminal C of the second capacitor 312 in FIG. 3A) of the second capacitor, the other terminal (e.g., the other terminal D of the second capacitor 312 in FIG. 3A) of the second capacitor is connected to one terminal (e.g., the one terminal E of the fourth capacitor 316 in FIG. 3A) of the fourth capacitor, the other terminal (e.g., the other terminal F of the fourth capacitor in FIG. 3A) of the fourth capacitor is connected to a second port (e.g., the second port 302 in FIG. 3A) of the high pass filter connected to the first band pass filter, one terminal (e.g., the one terminal G of the third capacitor 314 in FIG. 3A) of the third capacitor is connected to a first branched point (e.g., the first branched point 330 in FIG. 3A) of an electrical path between the one terminal of the first capacitor and the antenna, the other terminal (e.g., the other terminal H of the third capacitor 314 in FIG. 3A) of the third capacitor is connected to a second branched point (e.g., the second branched point 332 in FIG. 3A) of an electrical path between the other terminal of the second capacitor and the one terminal of the fourth capacitor, one terminal (e.g., the one terminal I of the first inductor 320 in FIG. 3A) of the first inductor is connected to a third branched point (e.g., the third branched point 334 in FIG. 3A) of an electrical path between the other terminal of the first capacitor and the one terminal of the second capacitor, the other terminal (e.g., the other terminal J of the first inductor 320 in FIG. 3A) of the first inductor is connected to a ground disposed or provided on the substrate, one terminal (e.g., the one terminal K of the second inductor 322 in FIG. 3A) of the second inductor is connected to a fourth branched point (e.g., the fourth branched point 336 in FIG. 3A) of an electrical path between the one terminal of the fourth capacitor and the second branched point, and the other terminal (e.g., the other terminal L of the second inductor 322 in FIG. 3A) of the second inductor is connected to a fifth branched point (e.g., the fifth branched point 338 in FIG. 3A) of an electrical path between the other terminal of the fourth capacitor and the second port of the high pass filter.

According to one or more embodiments, the first capacitor may be configured by a first conductive part (e.g., the first conductive part 310a of the first capacitor 310 in FIG. 3A) of a first layer (e.g., the first layer 391 in FIG. 3A) of the substrate and a second conductive part (e.g., the second conductive part 310b of the first capacitor 310 in FIG. 3A) of a second layer (e.g., the second layer 392 in FIG. 3A) stacked on a bottom of the first layer, the second capacitor may be configured by a third conductive part (e.g., the first conductive part 312a of the second capacitor 312 in FIG. 3A) of the first layer and a fourth conductive part (e.g., the second conductive part 312b of the second capacitor 312 in FIG. 3A) of the second layer, the third capacitor may be configured by the second conductive part of the second layer and a fifth conductive part (e.g., the first conductive part 314a of the third capacitor 314 in FIG. 3A) of a third layer (e.g., the third layer 393 in FIG. 3A) stacked on a bottom of the second layer, the fourth capacitor may be configured by a sixth conductive part (e.g., the first conductive part 316a of the fourth capacitor 316 in FIG. 3A) of the third layer and a seventh conductive part (e.g., the second conductive part 316b of the fourth capacitor 316 in FIG. 3A) of a fourth layer (e.g., the fourth layer 394 in FIG. 3A) stacked on a bottom of the third layer, the first inductor may be configured by a first conductive pattern (e.g., the conductive pattern 320a of the first inductor 320 in FIG. 3A) having a first length on the fourth layer, and the second inductor may be configured by a second conductive pattern (e.g., the conductive pattern 322a of the second inductor 322 in FIG. 3A) having a second length on the fourth layer.

According to one or more embodiments, the ground may include a ground pattern disposed or provided on each layer of the substrate.

According to one or more embodiments, the first port and the second port of the high pass filter may be disposed or provided on a surface of the substrate.

According to one or more embodiments, the first band pass filter and/or the second band pass filter may be arranged or provided on at least a partial area at least partially overlapping the high pass filter on the surface of the substrate.

According to one or more embodiments, the second band pass filter may be disposed or provided in a first area at least partially overlapping the high pass filter on the surface of the substrate, and the first band pass filter may be disposed or provided in a second area on the surface of the substrate, which is different from the first area and does not overlap the high pass filter disposed or provided on the substrate.

According to one or more embodiments, the first frequency band may include frequency bands of about 3 GHz or higher and the second frequency band may include frequency bands of about 3 GHz or lower.

According to one or more embodiments, a matching circuit disposed or provided on the second electrical path between the antenna and the second band pass filter may be further included.

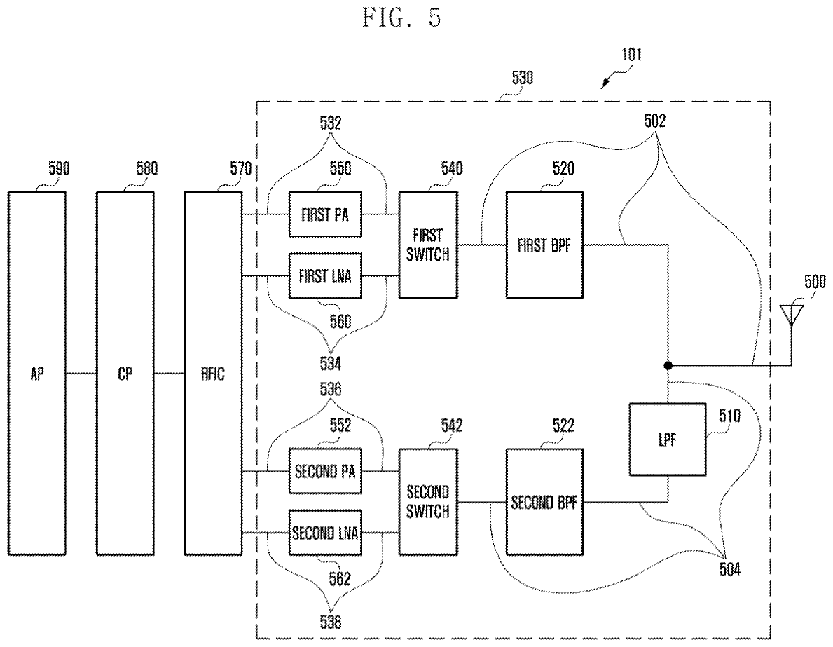

FIG. 5 is an example of a block diagram illustrating an electronic device including a low pass filter according to one or more embodiments.

According to various embodiment referring to FIG. 5, the electronic device 101 may include an antenna 500 (e.g., the antenna module 197 in FIG. 1), a radio frequency front end (RFFE) 530, a radio frequency integrated circuit (RFIC) 570, a communication processor (CP) 580 (e.g., the processor 120 or the auxiliary processor 123 in FIG. 1), and/or an application processor (AP) 590 (e.g., the processor 120 or the main processor 121 in FIG. 1). According to an embodiment, the RFFE 530 and/or the RFIC 570 may be substantially the same as the wireless communication circuit 192 in FIG. 1 or included in the wireless communication circuit 192. According to an embodiment, the RFIC 570, the communication processor (CP) 580, and the application processor (AP) 590 in FIG. 5 may operate similarly to the RFIC 270, the communication processor (CP) 280, and the application processor (AP) 290 in FIG. 2. Accordingly, a detailed description for the RFIC 570, the communication processor (CP) 580, and the application processor (AP) 590 will be omitted to avoid redundant description.

According to one or more embodiments, the RFFE 530 may include a low pass filter (LPF) 510, a first band pass filter (BPF) 520, a second band pass filter 522, a first switch 540, a second switch 542, a first power amplifier (PA) 550, a second power amplifier (PA) 552, a first low noise amplifier (LNA) 560, and/or a second low noise amplifier (LNA) 562. According to an embodiment, the first switch 540, the second switch 542, the first power amplifier 550, the second power amplifier 552, the first low noise amplifier 560 and/or the second low noise amplifier 562 in FIG. 5 may operate similarly to the first switch 240, the second switch 242, the first power amplifier 250, the second power amplifier 252, the first low noise amplifier 260 and/or the second low noise amplifier 262 in FIG. 2. Accordingly, a detailed description for the first switch 540, the second switch 542, the first power amplifier 550, the second power amplifier 552, the first low noise amplifier 560 and/or the second low noise amplifier 562 will be omitted to avoid redundant description.

According to one or more embodiments, the low pass filter 510 may be disposed or provided on a second electrical path 504 branched from the first electrical path 502 between the antenna 500 and the first band pass filter 520 and may filter a radio frequency (RF) signal of a second frequency band (e.g., about 3 GHz or lower). According to an embodiment, the low pass filter 510 may filter a signal of the second frequency band from the RF signal received through the antenna 500 and output the signal to the second band pass filter 522. According to an embodiment, the low pass filter 510 may filter a signal of the second frequency band from the RF signal provided from the second band pass filter 522 and output the signal to the antenna 500. According to an embodiment, the low pass filter 510 may be designed so that the second electrical path 504 is open in the first frequency band (e.g., about 3 GHz or higher). According to an embodiment, the low pass filter 510 may be configured such that the impedance is matched in the second band pass filter 522.

According to one or more embodiments, the second band pass filter 522 may be disposed or provided on the second electrical path 504 between the low pass filter 510 and the second switch 542 and may filter an RF signal in a fourth frequency band designated for transmission and/or reception of data in a network (e.g., the first network 198 or the second network 199 in FIG. 1). According to an embodiment, the second band pass filter 522 may filter a signal of the fourth frequency band from the signal of the second frequency band provided from the low pass filter 510 and output the signal to the second switch 542 (or the RFIC 570). According to an embodiment, the second band pass filter 522 may filter a signal of the fourth frequency band from the RF signal provided from the second switch 542 (or the RFIC 570) and output the signal to the low pass filter 510.

According to one or more embodiments, the first band pass filter 520 may be disposed or provided on the first electrical path 502 between the antenna 500 and the first switch 540 and may filter an RF signal in a third frequency band designated for transmission and/or reception of data in a network (e.g., the first network 198 or the second network 199 in FIG. 1). According to an embodiment, the first band pass filter 520 may filter a signal of the third frequency band from the signal of the first frequency band receive through the first electrical path 502 and output the signal to the first switch 540 (or the RFIC 570). According to an embodiment, the first band pass filter 520 may filter a signal of the third frequency band from the RF signal provided from the first switch 540 (or the RFIC 570) and output the signal to the antenna 500. According to an embodiment, the electronic device 101 may further include a matching circuit disposed or provided between the antenna 500 and the first band pass filter 520 on the first electrical path 502. For example, the matching circuit may be configured such that the impedance is matched in the first band pass filter 520. For example, the matching circuit may be designed so that the first electrical path 502 is open in the second frequency band (e.g., about 3 GHz or lower).

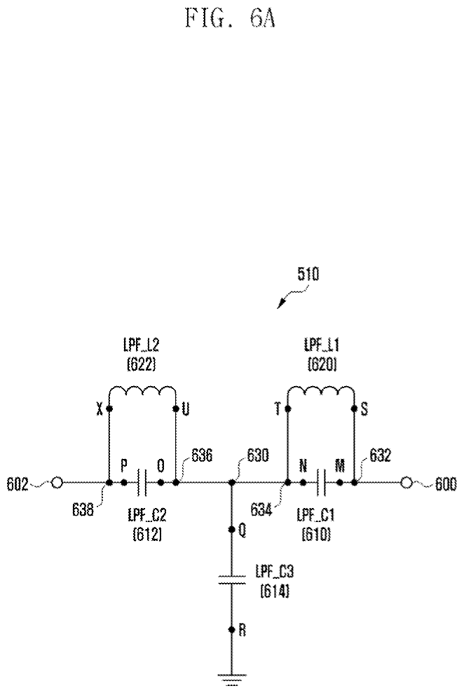

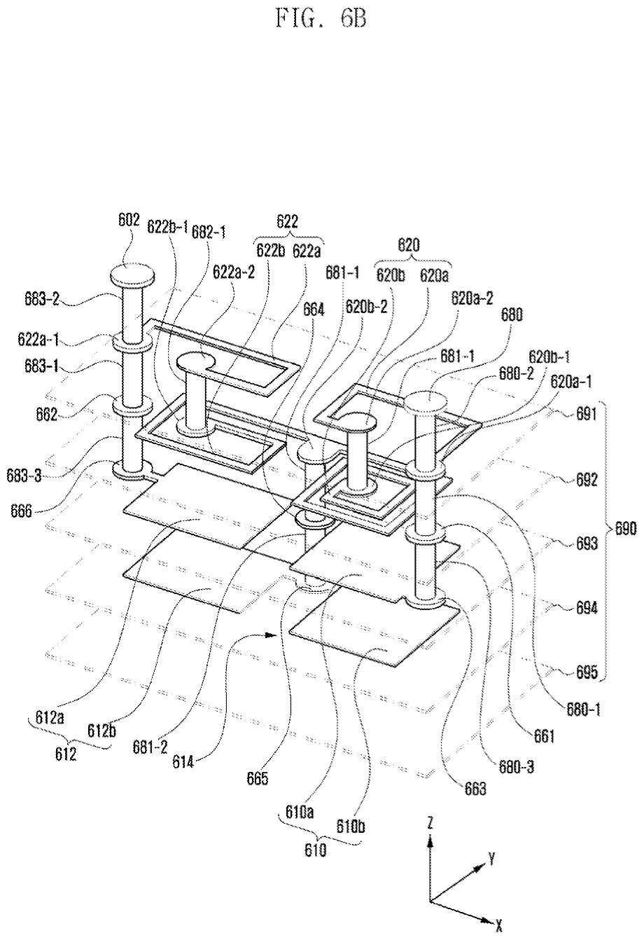

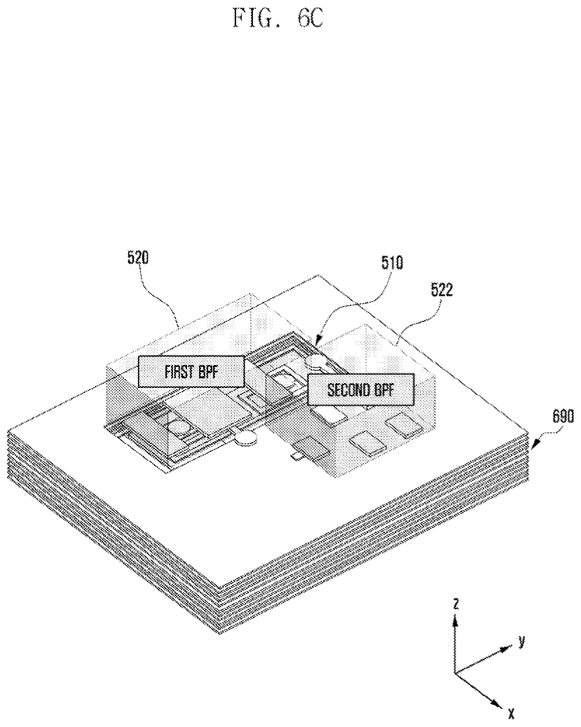

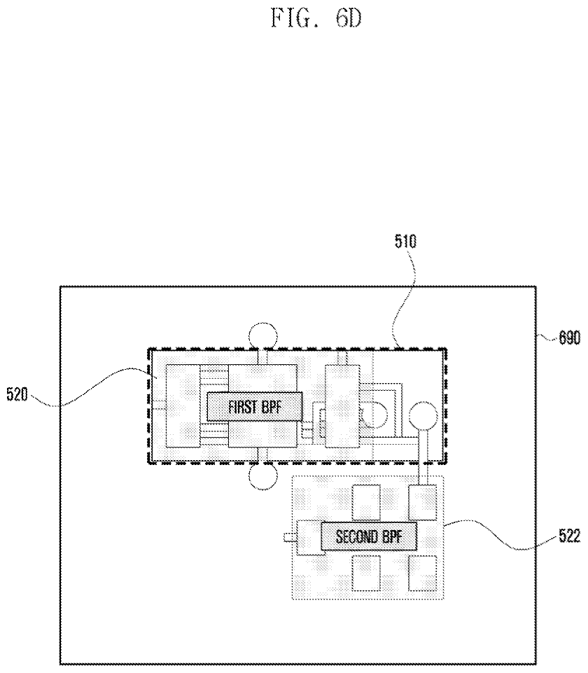

FIG. 6A is a circuit diagram of a low pass filter according to one or more embodiments.

According to one or more embodiments referring to FIG. 3A, the low pass filter 510 may include a first capacitor (LPF_C1) 610, a second capacitor (LPF_C2) 612, a third capacitor (LPF_C3) 614, a first inductor (LPF_L1) 620 and/or a second inductor (LPF_L2) 622.

According to one or more embodiments, one terminal M of the first capacitor 610 may be connected to a first port 600 of the low pass filter 510 and the other terminal N of the first capacitor 610 may be connected to one terminal O of the second capacitor 612. The other terminal P of the second capacitor 612 may be connected to a second port 602 of the low pass filter 510. For example, the first port 600 of the low pass filter 510 may be connected to the antenna 500 through the second electrical path 504. For example, the second port 602 of the low pass filter 510 may be connected to the second band pass filter 522 through the second electrical path 204.

According to one or more embodiments, one terminal Q of the third capacitor 614 may be connected to a first branched point 630 of an electrical path between the other terminal N of the first capacitor 610 and the one terminal O of the second capacitor 612. The other terminal R of the third capacitor 614 may be connected to a ground disposed or provided on a substrate 690. According to an embodiment, the substrate 690 may include a printed circuit board (PCB). By way of example, the ground may include a pattern disposed or provided on each layer (e.g., a first layer 691, a second layer 692, a third layer 693, a fourth layer 694, and a fifth layer 695) of the substrate 690.

According to one or more embodiments, one terminal S of the first inductor 620 may be connected to a second branched point 632 of an electrical path between the one terminal M of the first capacitor 610 and the first port 600. The other terminal T of the first inductor 620 may be connected to a third branched point 634 of an electrical path between the other terminal N of the first capacitor 610 and the first branched point 630.

According to one or more embodiments, one terminal U of the second inductor 622 may be connected to a fourth branched point 636 of an electrical path between the one terminal O of the second capacitor 612 and the first branched point 630. The other terminal X of the second inductor 622 may be connected to a fifth branched point 638 of an electrical path between the other terminal P of the second capacitor 612 and the second port 602.

According to one or more embodiments, in the circuit configuration of FIG. 6A, a combination of the first inductor 620, the second inductor 622, and the third capacitor 614 may operate as a filter for passing an RF signal of the second frequency band. A combination of the first capacitor 610 and the first inductor 620, and a combination of the second capacitor 612 and the second inductor 622 may operate as filters for blocking passage of an RF signal of the first frequency band.

FIG. 6B, FIG. 6C, and FIG. 6D are diagrams illustrating a stacking structure of a low pass filter according to one or more embodiments.

According to one or more embodiments referring to FIG. 6B, FIG. 6C, and FIG. 6D, the low pass filter 510 may be disposed or provided on the substrate 690. According to an embodiment, as shown in FIG. 6A, the first capacitor (LPF_C1) 610, the second capacitor (LPF_C2) 612, the third capacitor (LPF_C3) 614, the first inductor (LPF_L1) 620, and/or the second inductor (LPF_L2) 622 included in the low pass filter 510 may be configured as a stacking structure on the substrate 690. According to an embodiment, the substrate 690 may include a first layer 691, a second layer 692, a third layer 693, a fourth layer 694, and a fifth layer 695. According to an embodiment, the first layer 691, the second layer 692, the third layer 693, the fourth layer 694, and/or the fifth layer 695 may be sequentially stacked. For example, the substrate 690 may be disposed or provided in an internal space of a housing of the electronic device 101.

According to one or more embodiments, on the first layer 691, a first conductive pattern 620a of the first inductor 620 and/or a first conductive pattern 622a of the second inductor 622 may be configured. On the second layer 692, a second conductive pattern 620b of the first inductor 620 and a second conductive pattern 622b of the second inductor 622 may be configured.

According to an embodiment, one terminal 620a-1 of the first conductive pattern 620a of the first inductor 620 may be connected through a first via 680-1 to a first contact point 661 separated from the second conductive pattern 620b of the first inductor 620 on the second layer 692. According to an embodiment, the other terminal 620a-2 of the first conductive pattern 620a of the first inductor 620 may be connected through a second via 681-1 to the one terminal 620b-1 of the second conductive pattern 620b of the first inductor 620 on the second layer 692. For example, the first inductor 620 may include a conductive line having a coil shape and extending to the second conductive pattern 620b from the first conductive pattern 620a through the second via 681-1. For example, the one terminal 620a-1 of the first conductive pattern 620a of the first inductor 620 may be connected to the first port 600 of the low pass filter 510 through a third via 680-2.

According to an embodiment, one terminal 622a-1 of the first conductive pattern 622a of the second inductor 622 may be connected through a fourth via 683-1 to a second contact point 662 separated from the second conductive pattern 622b of the second inductor 622 on the second layer 692. According to an embodiment, the other terminal 622a-2 of the first conductive pattern 622a of the second inductor 622 may be connected through a fifth via 682-1 to the one terminal 622b-1 of the second conductive pattern 622b of the second inductor 622 on the second layer 692. For example, the second inductor 622 may include a conductive line having a coil shape and extending to the second conductive pattern 622b from the first conductive pattern 622a through the sixth via 682-1. For example, the one terminal 622a-1 of the first conductive pattern 622a of the second inductor 622 may be connected to the second port 602 of the low pass filter 510 through a seventh via 683-2.

According to one or more embodiments, on the third layer 693, a first conductive part 610a of the first capacitor 610 and a first conductive part 612a of the second capacitor 612 may be configured. On the fourth layer 694, a second conductive part 610b of the first capacitor 610 and a second conductive part 612b of the second capacitor 612 may be configured.

According to an embodiment, the first contact point 661 of the second layer 692 may be connected to a third contact point 663 extending from the first conductive part 610a of the first capacitor 610 through an eighth via 680-3.

According to an embodiment, the other terminal 620b-2 of the second conductive pattern 620b of the first inductor 620 in the second layer 692 may be connected through a ninth via 681-1 to a fourth contact point 664 separated from the first conductive part 610a of the first capacitor 610 in the third layer 693. On the fourth layer 694, the fourth contact point 664 may be connected to a fifth contact point 665 extending from the second conductive part 610b of the first capacitor 610 through a tenth via 681-2.

According to an embodiment, the second contact point 662 in the second layer 692 may be connected through an eleventh via 683-3 to a sixth contact point 666 connected to the first conductive part 612a of the second capacitor 612 in the third layer 693.

According to an embodiment, the first capacitor 610 may be configured by the first conductive part 610a of the first capacitor 610 disposed or provided on the third layer 693 and the second conductive part 610b of the first capacitor 610 disposed or provided on the fourth layer 694, which is configured to at least partially overlap the first conductive part 610a of the first capacitor 610 when viewed in the z-axis direction. According to an embodiment, the second capacitor 612 may be configured by the first conductive part 612a of the second capacitor 612 disposed or provided on the third layer 693 and the second conductive part 612b of the second capacitor 612 disposed or provided on the fourth layer 694, which is configured to at least partially overlap the first conductive part 612a of the second capacitor 612 when viewed in the z-axis direction. According to an embodiment, the third capacitor 614 may be configured by the second conductive part 610b of the first capacitor 610 disposed or provided on the fourth layer 694 or grounding of the second conductive part 612b of the second capacitor 612 and the fifth layer 695.

According to one or more embodiments, the first band pass filter 520 and the second band pass filter 522 may be arranged or provided on a surface of the substrate 690. According to an embodiment, when viewed in the z-axis direction, the first band pass filter 520 may be disposed or provided on a surface of the substrate 690 to overlap the low pass filter 510 and/or at least a portion of the low pass filter 510 disposed or provided on the substrate 690. According to an embodiment, the second band pass filter 522 may be disposed or provided on a surface of the substrate 690 not to overlap the low pass filter 510 disposed or provided on the substrate 690.

According to one or more embodiments, the first port 600 and the second port 602 of the low pass filter 510 may be disposed or provided on a surface of the substrate 690.

According to one or more embodiments, when viewed in the z-axis direction, the first band pass filter 520 and the second band pass filter 522 may be arranged or provided on a surface of the substrate 690 to overlap the low pass filter 510 and/or at least a portion of the low pass filter 510 disposed or provided on the substrate 690. According to an embodiment, when viewed in the z-axis direction, the first band pass filter 520 and the second band pass filter 522 may be arranged or provided on a surface of the substrate 690 to be included in an area of the low pass filter 510 disposed or provided on the substrate 690. In this case, the electronic device 101 may minimize and/or optimize wires for electrical connection among the first band pass filter 520, the second band pass filter 522, and/or the high pass filter 510.

According to one or more embodiments, when viewed in the z-axis direction, the second band pass filter 522 may be disposed or provided on a surface of the substrate 690 to overlap the low pass filter 510 and/or at least a portion of the low pass filter 510 disposed or provided on the substrate 690. The first band pass filter 520 may also be disposed or provided on a surface of the substrate 690 not to overlap the low pass filter 510 disposed or provided on the substrate 690.

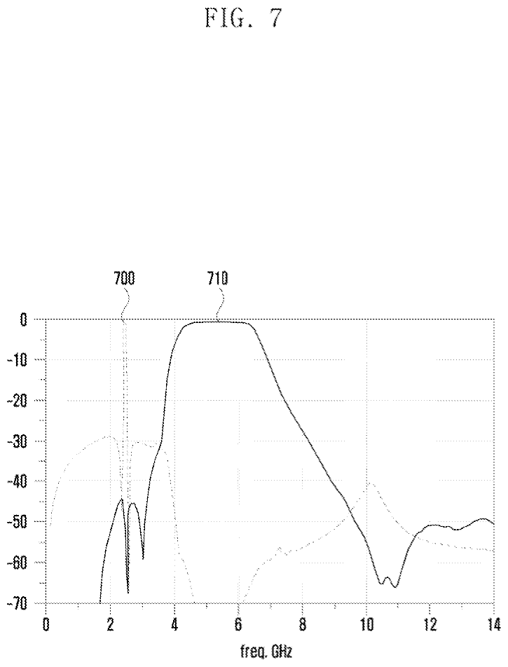

FIG. 7 is a graph depicting filtering performance of a low pass filter according to one or more embodiments. By way of example, the horizontal axis of FIG. 7 may represent frequency (GHz), and the vertical axis may represent signal level (dB).

According to various embodiment referring to FIG. 7, in case that the electronic device 101 uses the low pass filter 510, an RF signal of the first frequency band (e.g., about 3 GHz or higher) among RF signals received through the antenna 200 may be output to the first band pass filter 520 (710). In case that the electronic device 101 uses the low pass filter 510, an RF signal of the second frequency band (e.g., about 3 GHz or lower) among RF signals received through the antenna 200 may be output to the second band pass filter 522 through the low pass filter 510 (700).

According to one or more embodiments, an electronic device (e.g., the electronic device 101 in FIG. 1 or FIG. 5) may include an antenna (e.g., the antenna module 197 in FIG. 1 or the antenna 500 in FIG. 2), an RFFE (e.g., the wireless communication module 192 in FIG. 1 or the RFFE 530 in FIG. 5) electrically or operatively connected to the antenna, and an RFIC (e.g., the wireless communication module 192 in FIG. 1 or the RFIC 570 in FIG. 5) electrically or operatively connected to the RFFE, wherein the RFFE includes a first band pass filter (e.g., the first band pass filter 520 in FIG. 2, FIG. 5C, or FIG. 5D) disposed or provided on a first electrical path (e.g., the first electrical path 502 in FIG. 5) between the antenna and the RFIC and filtering a signal of a first frequency band, a low pass filter (e.g., the low pass filter 510 in FIG. 2, FIG. 6A, FIG. 6B, FIG. 6C, or FIG. 6D) disposed or provided on a second electrical path (e.g., the second electrical path 504 in FIG. 5) branched from the first electrical path between the antenna and the first band pass filter, and a second band pass filter (e.g., the second band pass filter 522 in FIG. 2, FIG. 6C, or FIG. 6D) disposed or provided on the second electrical path between the low pass filter and the RFIC and filtering a signal of a second frequency band relatively lower than the first frequency band.

According to one or more embodiments, the electronic device may further include a housing and a substrate (e.g., the substrate 690 in FIG. 6A, FIG. 6B, FIG. 6C, or FIG. 6D) disposed or provided inside the housing, and the low pass filter may be disposed or provided on the substrate.

According to one or more embodiments, the low pass filter may include a first capacitor (e.g., the first capacitor (LPF_C1) 610 in FIG. 6A), a second capacitor (e.g., the second capacitor (LPF_C2) 612 in FIG. 6A), a third capacitor (e.g., the third capacitor (LPF_C3) 614 in FIG. 6A), a first inductor (e.g., the first inductor (LPF_L1) 620 in FIG. 6A), and a second inductor (e.g., the second inductor (LPF_L2) 622 in FIG. 6A), wherein one terminal (e.g., the one terminal M of the first capacitor 610 in FIG. 6A) of the first capacitor is connected to a first port (e.g., the first port 600 in FIG. 6A) of the low pass filter connected to the antenna, the other terminal (e.g., the other terminal N of the first capacitor 610 in FIG. 6A) of the first capacitor is connected to one terminal (e.g., the one terminal O of the second capacitor 612 in FIG. 6A) of the second capacitor, the other terminal (e.g., the other terminal P of the second capacitor 612 in FIG. 6A) of the second capacitor is connected to a second port (e.g., the second port 602 in FIG. 6A) of the low pass filter connected to the second band pass filter, one terminal (e.g., the one terminal Q of the third capacitor 614 in FIG. 6A) of the third capacitor is connected to a first branched point (e.g., the first branched point 630 in FIG. 6A) of an electrical path between the other terminal of the first capacitor and the one terminal of the second capacitor, the other terminal (e.g., the other terminal R of the third capacitor 614 in FIG. 6A) of the third capacitor is connected to a ground disposed or provided on the substrate, one terminal (e.g., the one terminal S of the first inductor 620 in FIG. 6A) of the first inductor is connected to a second branched point (e.g., the second branched point 632 in FIG. 6A) of an electrical path between the one terminal of the first capacitor and the first port of the low pass filter, the other terminal (e.g., the other terminal T of the first inductor 620 in FIG. 6A) of the first inductor is connected to a third branched point (e.g., the third branched point 634 in FIG. 6A) of an electrical path between the other terminal of the first capacitor and the first branched point, one terminal (e.g., the one terminal U of the second inductor 622 in FIG. 6A) of the second inductor is connected to a fourth branched point (e.g., the fourth branched point 636 in FIG. 6A) of an electrical path between the one terminal of the second capacitor and the first branched point, and the other terminal (e.g., the other terminal X of the second inductor 622 in FIG. 6A) of the second inductor is connected to a fifth branched point (e.g., the fifth branched point 638 in FIG. 6A) of an electrical path between the other terminal of the second capacitor and the second port of the low pass filter.

According to one or more embodiments, the first inductor may be configured by a first conductive pattern (e.g., the first conductive pattern 620a of the first inductor 620 in FIG. 6B) of the first layer (e.g., the first layer 691 in FIG. 6B) and a second conductive pattern (e.g., the second conductive pattern 620b of the first inductor 620 in FIG. 6B) of a second layer (e.g., the second layer 692 in FIG. 6B) stacked on a bottom of the first layer, the second inductor may be configured by a third conductive pattern (e.g., the first conductive pattern 622a of the second inductor 622 in FIG. 6B) of the first layer and a fourth conductive pattern (e.g., the second conductive pattern 622b of the second inductor 622 in FIG. 6B) of the second layer, the first capacitor may be configured by a first conductive part (e.g., the first conductive part 610a of the first capacitor 610 in FIG. 6B) of a third layer (e.g., the third layer 693 in FIG. 6B) stacked on a bottom of the second layer and a second conductive part (e.g., the second conductive part 610b of the first capacitor 610 in FIG. 6B) of a fourth layer (e.g., the fourth layer 694 in FIG. 6B) stacked on a bottom of the third layer, the second capacitor may be configured by a third conductive part (e.g., the first conductive part 612a of the second capacitor 612 in FIG. 6B) of the third layer and a fourth conductive part (e.g., the second conductive part 612b of the second capacitor 612 in FIG. 6B) of the fourth layer, and the third capacitor may be configured by the second conductive part (e.g., the second conductive part 612b of the second capacitor 612 in FIG. 6B) of the fourth layer and a ground pattern of a fifth layer (e.g., the fifth layer 695 in FIG. 6B) stacked on a bottom of the fourth layer.

According to one or more embodiments, the ground may include a ground pattern disposed or provided on each layer of the substrate.

According to one or more embodiments, the first port and the second port of the low pass filter may be disposed or provided on a surface of the substrate.

According to one or more embodiments, the first band pass filter and/or the second band pass filter may be arranged or provided on at least a partial area at least partially overlapping the low pass filter on the surface of the substrate.

According to one or more embodiments, the first band pass filter may be disposed or provided in a first area at least partially overlapping the low pass filter on the surface of the substrate, and the second band pass filter may be disposed or provided in a second area on the surface of the substrate, which is different from the first area and does not overlap the low pass filter disposed or provided on the substrate.

According to one or more embodiments, the first frequency band may include frequency bands of about 3 GHz or higher and the second frequency band may include frequency bands of about 3 GHz or lower.

According to one or more embodiments, a matching circuit disposed or provided on the first electrical path between the antenna and the first band pass filter may be further included.

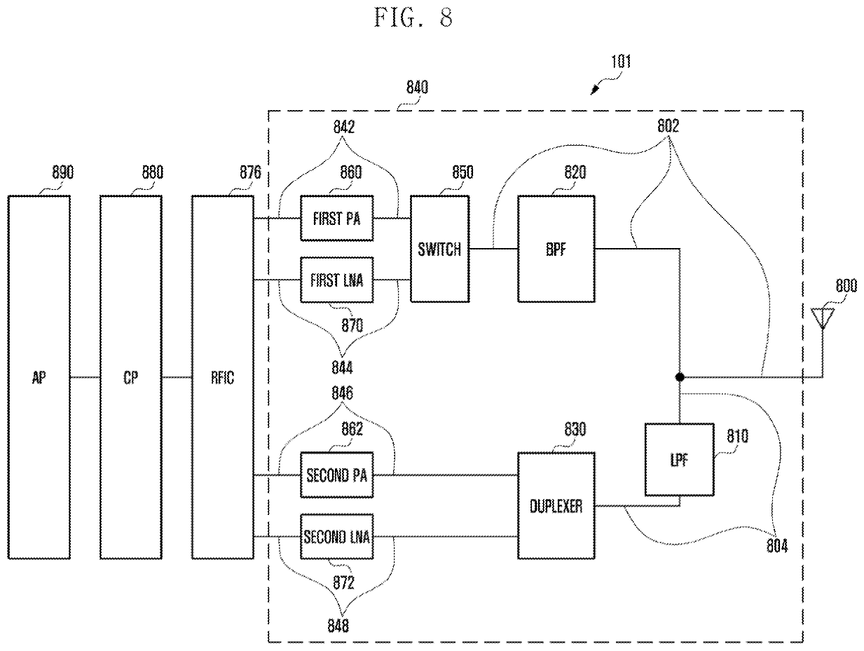

FIG. 8 is another example of an electronic device including a low pass filter according to one or more embodiments.

According to various embodiment referring to FIG. 8, the electronic device 101 may include an antenna 800 (e.g., the antenna module 197 in FIG. 1), a radio frequency front end (RFFE) 840, a radio frequency integrated circuit (RFIC) 876, a communication processor (CP) 880 (e.g., the processor 120 or the auxiliary processor 123 in FIG. 1), and/or an application processor (AP) 890 (e.g., the processor 120 or the main processor 121 in FIG. 1). According to an embodiment, the RFFE 840 and/or the RFIC 876 may be substantially the same as the wireless communication circuit 192 in FIG. 1 or included in the wireless communication circuit 192. According to an embodiment, the RFIC 876, the communication processor (CP) 880, and the application processor (AP) 890 in FIG. 8 may operate similarly to the RFIC 270, the communication processor (CP) 280, and the application processor (AP) 290 in FIG. 2. Accordingly, a detailed description for the RFIC 876, the communication processor (CP) 880, and the application processor (AP) 890 will be omitted to avoid redundant description.

According to one or more embodiments, the RFFE 840 may include a low pass filter (LPF) 810, a band pass filter (BPF) 820, a duplexer 830, a switch 850, a first power amplifier (PA) 860, a second power amplifier (PA) 862, a first low noise amplifier (LNA) 870, and/or a second low noise amplifier (LNA) 872.

According to one or more embodiments, the low pass filter 810 may be disposed or provided on a second electrical path 804 branched from the first electrical path 802 between the antenna 800 and the band pass filter 820 and may filter a radio frequency (RF) signal of a second frequency band (e.g., about 3 GHz or lower). According to an embodiment, the low pass filter 810 may filter a signal of the second frequency band from the RF signal received through the antenna 800 and output the signal to the duplexer 830. According to an embodiment, the low pass filter 810 may filter a signal of the second frequency band from the RF signal provided from the duplexer 830 and output the signal to the antenna 800. According to an embodiment, the low pass filter 810 may be designed so that the second electrical path 804 is open in the first frequency band (e.g., about 3 GHz or higher). According to an embodiment, the low pass filter 810 may be configured such that the impedance is matched in the duplexer 830. According to an embodiment, the low pass filter 810 may be disposed or provided on a substrate (e.g., the substrate 690 in FIG. 6B).

According to one or more embodiments, the duplexer 830 may be disposed or provided on the second electrical path 804 among the low pass filter 810, the second power amplifier 862, and/or the second low noise amplifier 872. According to an embodiment, the duplexer 830 may process an RF signal of a transmission frequency band and/or an RF signal of a reception frequency band designated to be used for data transmission to a network (e.g., the first network 198 or the second network 199 in FIG. 1). For example, the duplexer 830 may filter an RF signal of the reception frequency band from a signal of the second frequency band provided from the low pass filter 810 and output the RF signal to the second low noise amplifier 872 (or the RFIC 876). For example, the duplexer 830 may filter a signal of the transmission frequency band from the RF signal provided from the second power amplifier 862 (or the RFIC 876) and output the signal to the low pass filter 810.

According to one or more embodiments, the band pass filter 820 may be disposed or provided on the first electrical path 802 between the antenna 800 and the switch 850 and may filter an RF signal in a third frequency band designated for transmission and/or reception of data in a network (e.g., the first network 198 or the second network 199 in FIG. 1). According to an embodiment, the band pass filter 820 may filter a signal of the third frequency band from the signal of the first frequency band receive through the first electrical path 802 and output the signal to the switch 850 (or the RFIC 876). According to an embodiment, the band pass filter 820 may filter a signal of the third frequency band from the RF signal provided from the switch 850 (or the RFIC 876) and output the signal to the antenna 800. According to an embodiment, the electronic device 101 may further include a matching circuit disposed or provided between the antenna 800 and the band pass filter 820 on the first electrical path 802. For example, the matching circuit may be configured such that the impedance is matched in the band pass filter 820. For example, the matching circuit may be designed so that the first electrical path 802 is open in the second frequency band (e.g., about 3 GHz or lower).

According to one or more embodiments, the switch 850 may electrically or operatively connect the first electrical path 802 to the third electrical path 842 (e.g., the first power amplifier 860) or the fourth electrical path 844 (e.g., the first low power amplifier 870). According to an embodiment, when transmitting a signal by using the third frequency band, the switch 850 may electrically or operatively connect the first electrical path 802 and the third electrical path 842 (e.g., the first power amplifier 860), based on control of the communication processor 880. According to an embodiment, when receiving a signal by using the third frequency band, the switch 850 may electrically or operatively connect the first electrical path 802 and the fourth electrical path 844 (e.g., the first low power amplifier 870), based on control of the communication processor 880. According to an embodiment, the first power amplifier 860 may amplify the RF signal provided from the RFIC 876 and output the RF signal to the band pass filter 820 through the switch 850. According to an embodiment, the first low noise amplifier 870 may amplify low noise of the RF signal of the third frequency band provided from the band pass filter 820 through the switch 850 and output the RF signal to the RFIC 876.

According to one or more embodiments, the second power amplifier 862 may amplify the RF signal provided from the RFIC 876 and output the RF signal to the duplexer 830. According to one or more embodiments, the second low noise amplifier 872 may amplify low noise of the RF signal provided from the duplexer 830 and output the RF signal to the RFIC 876.

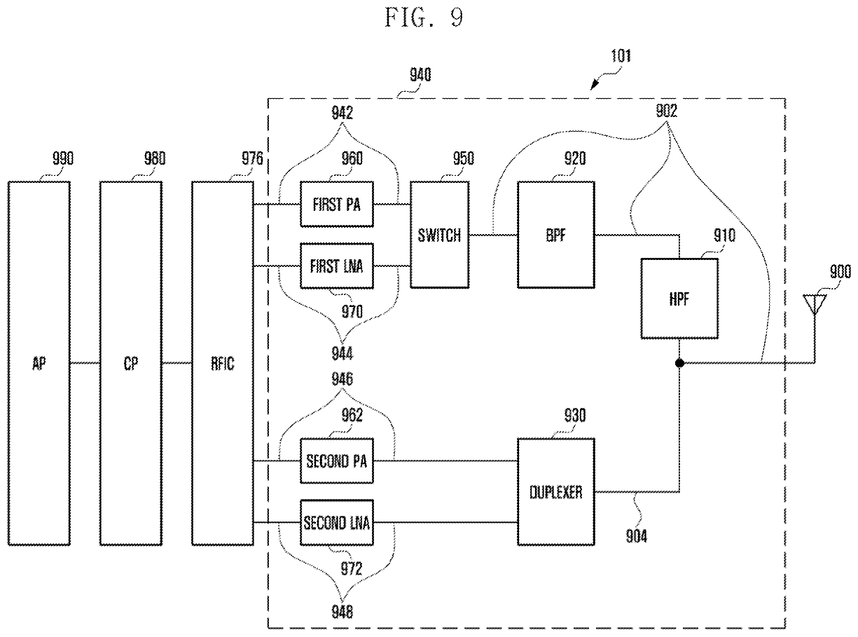

FIG. 9 is another example of an electronic device including a high pass filter according to one or more embodiments.

According to various embodiment referring to FIG. 9, the electronic device 101 may include an antenna 900 (e.g., the antenna module 197 in FIG. 1), a radio frequency front end (RFFE) 940, a radio frequency integrated circuit (RFIC) 976, a communication processor (CP) 980 (e.g., the processor 120 or the auxiliary processor 123 in FIG. 1), and/or an application processor (AP) 990 (e.g., the processor 120 or the main processor 121 in FIG. 1). According to an embodiment, the RFFE 940 and/or the RFIC 976 may be substantially the same as the wireless communication circuit 192 in FIG. 1 or included in the wireless communication circuit 192. According to an embodiment, the RFIC 976, the communication processor (CP) 980, and the application processor (AP) 990 in FIG. 9 may operate similarly to the RFIC 270, the communication processor (CP) 280, and the application processor (AP) 290 in FIG. 2. Accordingly, a detailed description for the RFIC 976, the communication processor (CP) 980, and the application processor (AP) 990 will be omitted to avoid redundant description.

According to one or more embodiments, the RFFE 940 may include a high pass filter (HPF) 910, a band pass filter (BPF) 920, a duplexer 930, a switch 950, a first power amplifier (PA) 960, a second power amplifier (PA) 962, a first low noise amplifier (LNA) 970, and/or a second low noise amplifier (LNA) 972. According to an embodiment, the switch 950, the first power amplifier 960, the second power amplifier 962, the first low noise amplifier 970 and/or the second low noise amplifier 972 in FIG. 9 may operate similarly to the switch 850, the first power amplifier 860, the second power amplifier 862, the first low noise amplifier 870 and/or the second low noise amplifier 872 in FIG. 8. Accordingly, a detailed description for the switch 950, the first power amplifier 960, the second power amplifier 962, the first low noise amplifier 970 and/or the second low noise amplifier 972 will be omitted to avoid redundant description.

According to one or more embodiments, the high pass filter 910 may be disposed or provided on a first electrical path 902 between the antenna 900 and the switch 950 and may filter a radio frequency (RF) signal of a first frequency band (e.g., about 3 GHz or higher). According to an embodiment, the high pass filter 910 may filter a signal of the first frequency band from the RF signal received through the antenna 900 and output the signal to the band pass filter 920. According to an embodiment, the high pass filter 910 may filter a signal of the first frequency band from the RF signal provided from the band pass filter 920 and output the signal to the antenna 900. According to an embodiment, the high pass filter 910 may be designed so that the first electrical path 902 is open in a second frequency band (e.g., about 3 GHz or lower). According to an embodiment, the high pass filter 910 may be configured such that the impedance is matched in the band pass filter 920. According to an embodiment, the high pass filter 910 may be disposed or provided on a substrate (e.g., the substrate 390 in FIG. 3B).

According to one or more embodiments, the band pass filter 920 may be disposed or provided on the first electrical path 902 between the high pass filter 910 and the switch 950 and may filter an RF signal in a third frequency band designated for transmission and/or reception of data in a network (e.g., the first network 198 or the second network 199 in FIG. 1). According to an embodiment, the band pass filter 920 may filter a signal of the third frequency band from the signal of the first frequency band provided from the high pass filter 910 and output the signal to the switch 950 (or the RFIC 976). According to an embodiment, the band pass filter 920 may filter a signal of the third frequency band from the RF signal provided from the switch 950 (or the RFIC 976) and output the signal to the high pass filter 910.

According to one or more embodiments, the duplexer 930 may be disposed or provided on a second electrical path 904 branched from the first electrical path 902 between the antenna 900 and the high pass filter 910. According to an embodiment, the duplexer 930 may process an RF signal of a transmission frequency band and/or an RF signal of a reception frequency band designated to be used for data transmission to a network (e.g., the first network 198 or the second network 199 in FIG. 1). For example, the duplexer 930 may filter an RF signal of the reception frequency band from a signal of the second frequency band received through the second electrical path 904 and output the RF signal to the second low noise amplifier 972 (or the RFIC 976). For example, the duplexer 930 may filter a signal of the transmission frequency band from the RF signal provided from the second power amplifier 962 (or the RFIC 976) and output the signal to the antenna 900.

The embodiments disclosed in the specification and the drawings are merely presented as specific examples to easily explain the technical features according to the embodiments of the disclosure and help understanding of the embodiments of the disclosure and are not intended to limit the scope of the embodiments of the disclosure. Therefore, the scope of the one or more embodiments disclosed herein should be construed as encompassing all changes or modifications derived from the technical ideas of the one or more embodiments disclosed herein in addition to the embodiments disclosed herein.

What is claimed is:

1. An electronic device comprising:
an antenna;
a radio frequency front end (RFFE) operatively connected to the antenna; and
a radio frequency integrated circuit (RFIC) operatively connected to the RFFE,
wherein the RFFE comprises:
a high pass filter provided on a first electrical path between the antenna and the RFIC;
a first band pass filter provided on the first electrical path between the high pass filter and the RFIC, the first band pass filter being configured to filter a signal of a first frequency band; and
a second band pass filter provided on a second electrical path branched from the first electrical path between the antenna and the high pass filter, the second band pass filter being configured to filter a signal of a second frequency band relatively lower than the first frequency band.

2. The electronic device of claim 1, further comprising:
a housing; and
a substrate provided inside the housing,
wherein the high pass filter is provided on the substrate.

3. The electronic device of claim 2, wherein the substrate comprises a plurality of layers that are stacked, and
wherein the high pass filter is provided on the plurality of layers.

4. The electronic device of claim 2, wherein the high pass filter comprises a first capacitor, a second capacitor, a third capacitor, a fourth capacitor, a first inductor, and a second inductor,
wherein a first terminal of the first capacitor is connected to a first port of the high pass filter connected to the antenna, and a second terminal of the first capacitor is connected to a first terminal of the second capacitor,
wherein a second terminal of the second capacitor is connected to a first terminal of the fourth capacitor,
wherein a second terminal of the fourth capacitor is connected to a second port of the high pass filter connected to the first band pass filter,
wherein a first terminal of the third capacitor is connected to a first branched point of an electrical path between the first terminal of the first capacitor and the antenna, and a second terminal of the third capacitor is connected to a second branched point of an electrical path between the second terminal of the second capacitor and the first terminal of the fourth capacitor,
wherein a first terminal of the first inductor is connected to a third branched point of an electrical path between the second terminal of the first capacitor and the first terminal of the second capacitor, and a second terminal of the first inductor is connected to a ground provided on the substrate, and
wherein a first terminal of the second inductor is connected to a fourth branched point of an electrical path between the first terminal of the fourth capacitor and the second branched point, and a second terminal of the second inductor is connected to a fifth branched point of an electrical path between the second terminal of the fourth capacitor and the second port of the high pass filter.

5. The electronic device of claim 4, wherein the plurality of layers of the substrate comprise a first layer, a second on a bottom of the first layer, a third layer stacked on a bottom of the second layer, and a fourth layer on a bottom of the third layer,
wherein the first capacitor comprises a first conductive part of the first layer of the substrate and a second conductive part of the second layer,
wherein the second capacitor comprises a third conductive part of the first layer and a fourth conductive part of the second layer,
wherein the third capacitor comprises the second conductive part of the second layer and a fifth conductive part of the third layer,
wherein the fourth capacitor comprises a sixth conductive part of the third layer and a seventh conductive part of the fourth layer,
wherein the first inductor comprises a first conductive pattern having a first length on the fourth layer, and
wherein the second inductor comprises a second conductive pattern having a second length on the fourth layer.

6. The electronic device of claim 5, wherein the ground comprises a ground pattern provided on each layer of the plurality of layers of the substrate.

7. The electronic device of claim 4, wherein the first port and the second port of the high pass filter are provided on a surface of the substrate.

8. The electronic device of claim 2, wherein the first band pass filter or the second band pass filter is provided on at least a partial area at least partially overlapping the high pass filter on a surface of the substrate.

9. The electronic device of claim 2, wherein the second band pass filter is provided in a first area at least partially overlapping the high pass filter on a surface of the substrate, and
wherein the first band pass filter is provided in a second area on a surface of the substrate, which is different from the first area, the first band pass filter being not overlapping the high pass filter provided on the substrate.

10. The electronic device of claim 1, wherein the first frequency band comprises a frequency band of 3 GHz or higher, and
wherein the second frequency band comprises a frequency band of 3 GHz or lower.

11. The electronic device of claim 1, further comprising a matching circuit provided on the second electrical path between the antenna and the second band pass filter.

12. The electronic device of claim 11, wherein the matching circuit is configured so that the second electrical path is open in the first frequency band.

13. The electronic device of claim 1, wherein the high pass filter is configured so that the first electrical path is open in the second frequency band.

14. The electronic device of claim 1, wherein the RFFE further comprises:
a first amplification circuit configured to amplify a first radio frequency (RF) signal provided from the RFIC and output the first RF signal to the first band pass filter;
a first low noise amplification circuit configured to amplify low noise of a second RF signal provided from the first band pass filter and output the second RF signal to the RFIC;
a second amplification circuit configured to amplify a third RF signal provided from the RFIC and output the third RF signal to the second band pass filter; and
a second low noise amplification circuit configured to amplify low noise of a fourth RF signal provided from the second band pass filter and output the fourth RF signal to the RFIC.

15. The electronic device of claim 1, further comprising a processor operatively connected to the RFIC,
wherein the processor is configured to process a baseband signal provided from the RFIC.

16. An electronic device comprising:
an antenna;
a radio frequency front end (RFFE) operatively connected to the antenna; and
a radio frequency integrated circuit (RFIC) operatively connected to the RFFE,
wherein the RFFE comprises:
a first band pass filter provided on the first electrical path between the antenna and the RFIC, the first band pass filter being configured to filter a signal of a first frequency band;
a low pass filter provided on a second electrical path branched from the first electrical path between the antenna and the first band pass filter ; and
a second band pass filter provided on the second electrical path between the low pass filter and the RFIC, the second band pass filter being configured to filter a signal of a second frequency band relatively lower than the first frequency band.

17. The electronic device of claim 16, further comprising:
a housing; and
a substrate provided inside the housing,
wherein the low pass filter is provided on the substrate.

18. The electronic device of claim 17, wherein the low pass filter comprises a first capacitor, a second capacitor, a third capacitor, a first inductor, and a second inductor,
wherein a first terminal of the first capacitor is connected to a first port of the low pass filter connected to the antenna, and a second terminal of the first capacitor is connected to a first terminal of the second capacitor,
wherein a second terminal of the second capacitor is connected to a second port of the low pass filter connected to the second band pass filter,
wherein a first terminal of the third capacitor is connected to a first branched point of an electrical path between the second terminal of the first capacitor and the first terminal of the second capacitor, and a second terminal of the third capacitor is connected to a ground provided on the substrate,
wherein a first terminal of the first inductor is connected to a second branched point of an electrical path between the first terminal of the first capacitor and the first port of the low pass filter, and a second terminal of the first inductor is connected to a third branched point of an electrical path between the second terminal of the first capacitor and the first branched point, and
wherein a first terminal of the second inductor is connected to a fourth branched point of an electrical path between the first terminal of the second capacitor and the first branched point, and a second terminal of the second inductor is connected to a fifth branched point of an electrical path between the second terminal of the second capacitor and the second port of the low pass filter.

19. The electronic device of claim 18, wherein the plurality of layers of the substrate comprise a first layer, a second on a bottom of the first layer, a third layer stacked on a bottom of the second layer, and a fourth layer on a bottom of the third layer,
wherein the first inductor comprises a first conductive pattern of the first layer of the substrate and a second conductive pattern of the second layer,
wherein the second inductor comprises a third conductive pattern of the first layer and a fourth conductive pattern of the second layer,
wherein the first capacitor comprises the first conductive part of the third layer and a second conductive part of the fourth layer,
wherein the second capacitor comprises a third conductive part of the third layer and a fourth conductive part of the fourth layer, and
wherein the third capacitor comprises the second conductive part of the fourth layer and a ground pattern of the fifth layer.

20. The electronic device of claim 18, wherein the first port and the second port of the low pass filter are provided on a surface of the substrate.
